(19) United States
(12) Patent Application Publication
(10) Pub. No.: US 2009/0141465 A1
(43) Pub. Date: Jun. 4, 2009

(54) ELECTRONIC APPARATUS AND CIRCUIT BOARD

(75) Inventors: Tomoaki Tamura, Ome-shi (JP); Masayuki Sanada, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/208,854

(22) Filed: Sep. 11, 2008

(30) Foreign Application Priority Data
Nov. 29, 2007 (JP) 2007-308781

(51) Int. Cl. H05K 7/10

(52) U.S. Cl. 361/777

(57) ABSTRACT

According to one embodiment, a circuit board carries thereon a connection pattern for the connection of a PC card receptacle selectively mounted in a mounting area, a connection pattern for the connection of an Express card receptacle, and a connection pattern for the connection of a smartcard receptacle. An end portion of the smartcard receptacle overlaps the connection pattern for the Express card receptacle. Therefore, the smartcard receptacle is connected to the connection pattern for the smartcard receptacle through a flexible printed wiring element and a connector with the connection pattern shifted to a position between the two connection patterns.

### CROSS-REFERENCE TO RELATED APPLICATIONS

This application is based upon and claims the benefit of priority from Japanese Patent Application No. 2007-308781, filed Nov. 29, 2007, the entire contents of which are incorporated herein by reference.

### BACKGROUND

1. Field

One embodiment of the invention relates to an electronic apparatus, such as a portable computer, and a circuit board incorporated in the electronic apparatus.

2. Description of the Related Art

An electronic apparatus, such as a portable computer, is generally constructed so that a case contains a circuit board on which a plurality of electronic components are mounted. The circuit board of the electronic apparatus of this type is also mounted with a storage device, such as a hard disc drive (HDD), semiconductor memory, etc. It is disclosed by, for example, Jpn. Pat. Appln. KOKAI Publication No. 9-97124.

This disclosed device is characterized in that a base portion for mounting the HDD on the circuit board doubles as one for mounting a memory board that carries the semiconductor memory thereon. The HDD or the memory board can be selectively mounted in the same space.

In mounting a device such as a PC card receptacle, whose shape is determined by a card to be mounted, in a specific position (near the inside of a side face of the case of the electronic apparatus) on the circuit board, however, the position of a board-side connection terminal that connects the card receptacle of the specific shape to the circuit board is unmistakably determined by the type (or external shape) of the card receptacle.

In selectively mounting card receptacles of different types or shapes in the same position on the circuit board, therefore, some combinations of card receptacles cannot be mounted selectively, depending on the position of the connection terminal. Thus, card receptacles of two types that have connection terminals situated overlapping each other on the circuit board cannot be mounted alternatively.

In this case, separate spaces must be provided for the card receptacles to be mounted on the circuit board, so that the mounting space on the circuit board is narrowed inevitably. In this case, moreover, a user who expects to mount only one of the card receptacles is forced to overlook a useless space for an unnecessary type of card receptacle on the circuit board.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not limit the scope of the invention.

FIG. 1 is an external perspective view showing a portable computer according to one embodiment of the invention;

FIG. 2 is a schematic plan view showing a circuit board incorporated in the portable computer of FIG. 1;

FIG. 3 is a partial enlarged view showing the circuit board of FIG. 2 without being loaded with a PC card receptacle;

FIG. 4 is a schematic plan view showing an Express card receptacle mounted in a mounting area on the circuit board of FIG. 2; and

FIG. 5 is a schematic plan view showing a smartcard receptacle mounted in the mounting area on the circuit board of FIG. 2.

### DETAILED DESCRIPTION

Various embodiments according to the invention will be described hereinafter with reference to the accompanying drawings. In general, according to one embodiment of the invention, an electronic apparatus 1 includes a case 4 and a circuit board 20, which is mounted with a plurality of electronic components and contained in the case 4. The case 4 is provided with a card insertion aperture 9, and a first card receptacle 22 is mounted on the circuit board 20 so as to communicate with the aperture 9. Further, a first connection terminal 26 that connects the first card receptacle 22 to the circuit board 20 is disposed on the circuit board. Furthermore, a second connection terminal 27 separate from the first connection terminal 26 is disposed on the circuit board 20. It serves to mount, in place of the first card receptacle 22, a second card receptacle 23, which has a connection terminal overlapping the first connection terminal 26, on the circuit board 20.

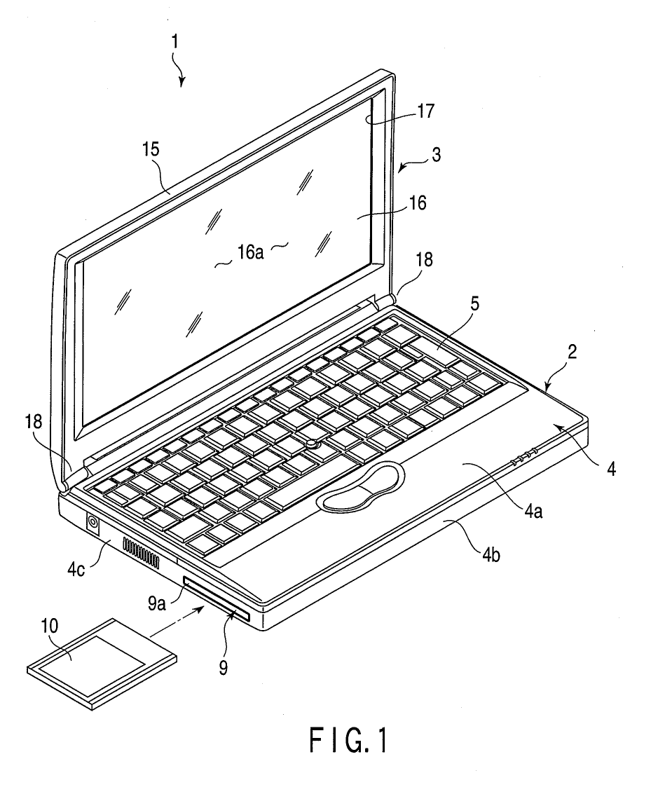

FIG. 1 is an external perspective view showing a portable computer 1 as an example of the electronic apparatus according to the embodiment of the invention. In the state shown in FIG. 1, a display unit 3 is open with respect to a computer body 2.

The computer body 2 is provided with the case 4 in the form of a flat rectangular box. The case 4 includes a bottom wall (not shown), top wall 4a, front wall 4b, right sidewall (not shown), left sidewall 4c, and rear wall (not shown). A keyboard 5 including a pointing device is disposed on the top wall 4a of the case 4.

The left sidewall 4c of the case 4 is provided with the card insertion aperture 9 through which a PC card 10 can be inserted or removed. The card insertion aperture 9 is covered by a swingable lid 9a. In the present embodiment, a smartcard or Express card (mentioned later), besides the PC card 10, can also be inserted or removed through the insertion aperture 9. Specifically, a card receptacle (mentioned later) that is compatible with the type of card to be inserted is exclusively provided within the card insertion aperture 9.

The display unit 3 is provided with a display housing 15 and a liquid crystal panel 16 contained therein. The panel 16 includes a display screen 16a. The display screen 16a is exposed to the inside of the display housing 15 through an opening 17 in the front face of the housing.

The display housing 15 is rockably mounted on the rear end portion of the case 4 by a hinge 18. Thus, the display unit 3 is swingable between a closed position in which it is level so as to cover the top wall 4a of the case 4 and the keyboard 5 from above and an open position in which it is raised so that the top wall 4a, keyboard 5, and display screen 16a are exposed.

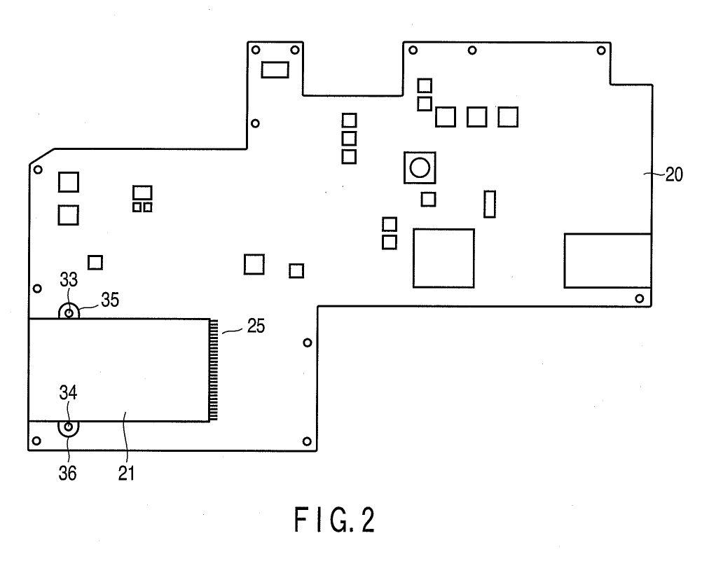

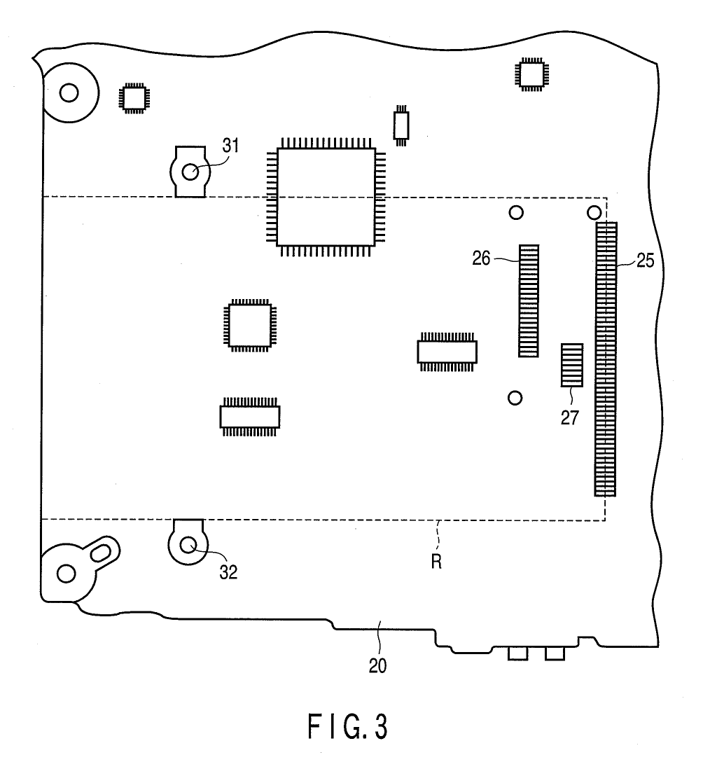

FIG. 2 shows a schematic view of the circuit board 20 contained in the case 4 of the computer body 2. The circuit board 20 is mounted with the electronic components and fitted with a PC card receptacle 21, which communicates with the card insertion aperture 9 of the case 4. FIG. 3 shows a partial enlarged view of the circuit board 20 without being loaded with the PC card receptacle 21. In FIG. 3, broken line R indicates a mounting area from which the card receptacle 21 is removed.

The PC card receptacle 21 has an external shape one size larger than that of the PC card 10, which is inserted through the card insertion aperture 9, and is mounted in a position that communicates with the card insertion aperture. Thus, the mounting position R for the PC card receptacle 21 on the circuit board 20 is unmistakably determined by the type of card to be mounted. Also, the position of a connection pattern 25 on the circuit board 20 for electrical connection of the PC card receptacle 21 is unmistakably determined by the external shape of the receptacle 21. Specifically, the connection pattern 25 for the PC card receptacle 21 is situated overlapping an end portion of the receptacle 21 that is more remote from the card insertion aperture 9.

The circuit board 20 is formed with two through mounting holes 31 and 32 (see FIG. 3) that constitute a mounting structure for mounting the PC card receptacle 21 on the circuit board 20. This mounting structure further includes lugs 35 and 36 (see FIG. 2) that protrude from the PC card receptacle 21. The lugs 35 and 36 have threaded holes 33 and 34 that are aligned with the mounting holes 31 and 32 of the circuit board 20, respectively.

In mounting the PC card receptacle 21 on the circuit board 20, the receptacle 21 is put on the mounting area R on the circuit board 20, and the threaded holes 33 and 34 of the two lugs 35 and 36 are aligned with the mounting holes 31 and 32, respectively, of the circuit board 20. Then, screws (not shown) are passed individually through the two mounting holes 31 and 32 from the reverse side of the circuit board 20 and threadedly fixed to the threaded holes 33 and 34.

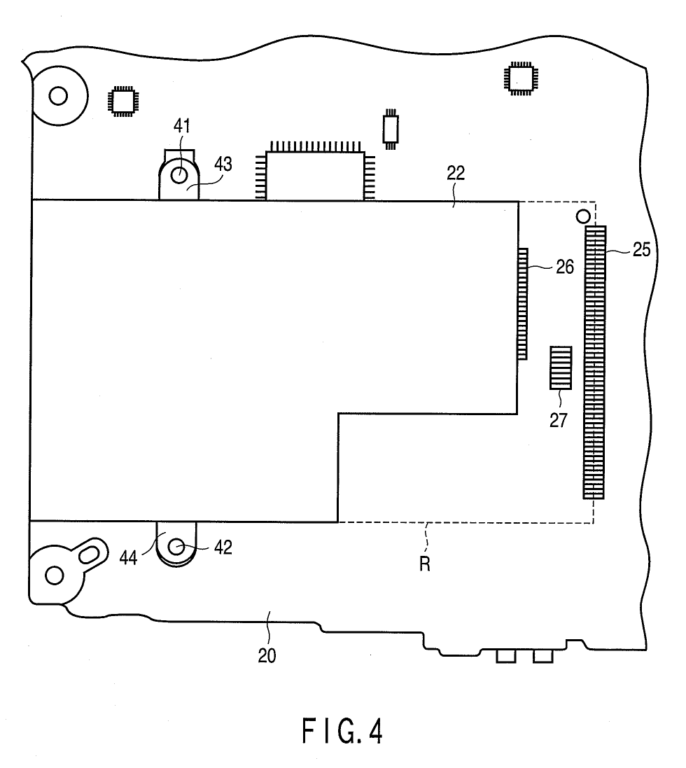

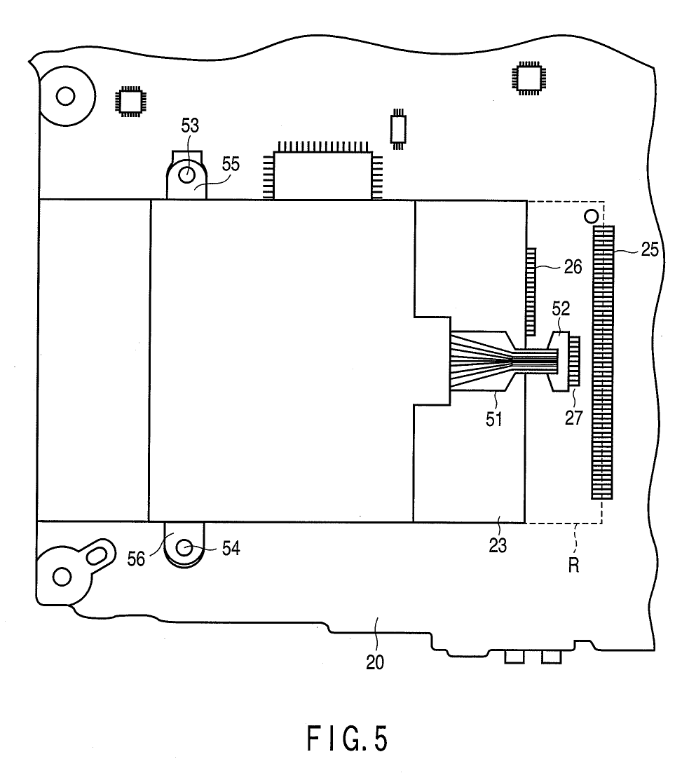

In the portable computer 1 of the present embodiment, the Express card receptacle 22 (first card receptacle) shown in FIG. 4 or the smartcard receptacle 23 (second card receptacle) shown in FIG. 5 can be mounted in place of the PC card receptacle 21 in the mounting area R of the circuit board 20.

In mounting the Express card receptacle 22, as shown in FIG. 4, the receptacle 22 is put on the mounting area R on the circuit board 20, and a connection terminal (not shown) at an end portion of the receptacle 22 is connected to the connection pattern (first connection terminal) 26 on the circuit board 20. The Express card receptacle 22 also has an external shape that depends on that of the Express card (not shown in FIG. 4) and is mounted so as to communicate with the card insertion aperture 9 of the case 4. Therefore, the position of the connection pattern 26 on the circuit board side is also determined unmistakably. The connection pattern 26 is formed in a position nearer to the card insertion aperture 9 than the connection pattern 25 for the PC card receptacle 21 is.

Furthermore, two lugs 55 and 56 that are formed with threaded holes 53 and 54, respectively, protrude from the Express card receptacle 22 and constitute a mounting structure for mounting the receptacle 22 on the circuit board 20. These two threaded holes 41 and 42 are formed in the same positions as the threaded holes 33 and 34 in the lugs 35 and 36 of the PC card receptacle 21 and aligned with the mounting holes 31 and 32, respectively, of the circuit board 20. Thus, the mounting holes 31 and 32 of the circuit board 20 share the mounting structure in common with the PC card receptacle 21.

In mounting the smartcard receptacle 23 on the circuit board 20, as shown in FIG. 5, the receptacle 23 is put on the mounting area R on the circuit board 20, and a connection terminal of the receptacle 23 is connected to the connection pattern (second connection terminal) 27 on the circuit board 20 through a flexible printed wiring element 51 and a connector 52.

Thus, if a connection terminal is disposed at an end portion of the smartcard receptacle 23 that is more remote from the card insertion aperture 9 and connected directly to the circuit board 20, in this case, it inevitably overlaps the connection pattern 26 for the Express card receptacle 22. Therefore, the connection pattern 27 on the circuit board side for the smartcard receptacle 23 is formed in a position separate from the connection pattern 26. The flexible printed wiring element 51 is used to connect the smartcard receptacle 23 to the separately formed connection pattern 27.

Further, two lugs 43 and 44 that are formed with threaded holes 41 and 42, respectively, protrude from the Express card receptacle 22 and constitute a mounting structure for mounting the receptacle 22 on the circuit board 20. These two threaded holes 41 and 42 are formed in the same positions as the threaded holes 33 and 34 in the lugs 35 and 36 of the PC card receptacle 21 and aligned with the mounting holes 31 and 32, respectively, of the circuit board 20. Thus, the mounting holes 31 and 32 of the circuit board 20 share the mounting structure in common with the PC card receptacle 21.

According to the present embodiment, as described above, the PC card receptacle 21, Express card receptacle 22, and smartcard receptacle 23 can be selectively mounted in the mounting area R on the circuit board 20 in the position that communicates with the card insertion aperture 9 of the case 4.

While a certain embodiment of the invention has been described, the embodiment has been presented by way of example only, and is not intended to limit the scope of the invention. Indeed, the novel method and system described herein may be embodied in a variety of other forms. Furthermore, various omissions, substitutions and changes in the form of the method and system described herein may be made without departing from the spirit of the invention. The accompanying claims and their equivalents are intended to cover such forms or modifications as would fall within the scope and spirit of the invention.

In connection with the foregoing embodiment, for example, there has been described the structure for selectively mounting the card receptacles 21, 22, and 23 of three types in the same position R on the circuit board 20. Alternatively, however, card receptacles of four or more types with different shapes can be mounted selectively.

What is claimed is:

1. An electronic apparatus comprising:
a case;
a circuit board mounted with a plurality of electronic components and contained in the case;
a card insertion slot provided in the case;
a first card receptacle on the circuit board configured to be connected to the card insertion slot;
a first connection terminal on the circuit board configured to connect the first card receptacle to the circuit board; and
a second connection terminal positioned separately from the first connection terminal on the circuit board in order to mount a second card receptacle in a place of the first card receptacle on the circuit board, the second card receptacle comprising a contact point overlapping the first connection terminal.

2. The electronic apparatus of claim 1, further comprising a wiring element for connecting the second card receptacle to the second connection terminal.

3. The electronic apparatus of claim 2, further comprising a common mounting structure on the circuit board configured to selectively mount either the first or second card receptacle on the circuit board.

4. A circuit board contained in a case of an electronic apparatus, comprising:
a first connection terminal for connecting between the circuit board and a first card receptacle to be mounted on the circuit board via a card insertion slot of the case; and
a second connection terminal positioned separately from the first connection terminal in order to mount a second card receptacle in place of the first card receptacle, the second card receptacle comprising a contact point overlapping the first connection terminal.

5. The circuit board of claim 4, further comprising a common mounting structure for selectively mounting either the first or second card receptacle on the circuit board.
